(19) United States
(12) Patent Application Publication
(10) Pub. No.: US 2026/0173765 A1
(43) Pub. Date: Jun. 18, 2026

(54) SEMICONDUCTOR DEVICE AND METHOD FOR FABRICATING THE SAME

(71) Applicant: SK hynix Inc., Gyeonggi-do (KR)

(72) Inventors: Ku Youl JUNG, Gyeonggi-do (KR); Jung Hyeok KWAK, Gyeonggi-do (KR); Tae Yup KIM, Gyeonggi-do (KR); Jin Won JUNG, Gyeonggi-do (KR); Young Ki CHAI, Gyeonggi-do (KR)

(21) Appl. No.: 19/258,901

(22) Filed: Jul. 3, 2025

(30) Foreign Application Priority Data
Dec. 18, 2024 (KR) 10-2024-0189468

(51) Int. Cl. H10N 50/10; H10N 50/01

(52) U.S. Cl. CPC H10N 50/10; H10N 50/01

(57) ABSTRACT

A semiconductor device, and a method for fabricating the semiconductor device, the semiconductor device including an interlayer insulating film disposed on a substrate, the interlayer insulating film having a recess exposing a portion of the substrate; a bottom electrode contact (BEC) embedded in at least a portion of the recess; and an MTJ layer disposed on the interlayer insulating film and the bottom electrode contact, wherein the bottom electrode contact comprises a Co alloy, Fe alloy, Ni alloy, or Mn alloy comprising at least one selected from the group consisting of Pt, Pd, Al, Ga, B, Ir, Zr, Hf, and rare earth metals.

### CROSS-REFERENCE TO RELATED APPLICATIONS

The present application claims priority under 35 U.S.C 119(a) to Korean Patent Application No. 10-2024-0189468, filed on Dec. 18, 2024, which is incorporated herein by reference in its entirety.

### BACKGROUND

### 1. Field

Embodiments of the present disclosure relate generally to semiconductor technology, and more particularly, to a semiconductor device with a magnetic tunnel junction structure, and a method for fabricating the semiconductor device.

### 2. Description of the Related Art

Recently, semiconductor devices capable of storing data in diverse electronic devices, such as computers and portable communication devices, are demanded to cope with the trends of miniaturization, low power consumption, high performance, and diversification of electronic devices. As a result, significant research and development efforts are expended in the semiconductor industry to study and develop such semiconductor devices. Generally, semiconductor devices include those capable of storing data by taking advantage of the characteristics of switching between different resistance states according to the applied voltage or current, for example, a Resistive Random Access Memory (RRAM), a Phase-change Random Access Memory (PRAM), a Ferroelectric Random Access Memory (FRAM), a Magnetic Random Access Memory (MRAM), an e-fuse and the like.

### SUMMARY

Embodiments of the present disclosure are directed to a semiconductor device and a method of manufacturing the same that can achieve an increase in magnetoresistance (MR) and an increase in exchange bias field (Hex) by forming a layer that simultaneously functions as a shift canceling layer (SCL) and a bottom electrode contact (BEC) without forming a separate shift canceling layer (SCL) using a specific alloy, thereby reducing the height of the magnetic tunnel junction (MTJ) structure while enabling high temperature heat treatment.

In accordance with an embodiment of the present disclosure, a semiconductor device includes an interlayer insulating film disposed on a substrate and having a recess exposing a portion of the substrate; a bottom electrode contact (BEC) embedded in at least a portion of the recess; and an MTJ layer disposed on the interlayer insulating film and the bottom electrode contact, wherein the bottom electrode contact comprises a Co alloy, a Fe alloy, a Ni alloy, or a Mn alloy comprising at least one selected from the group consisting of Pt, Pd, Al, Ga, B, Ir, Zr, Hf, and rare earth metals.

In accordance with another embodiment of the present disclosure, a method for fabricating a semiconductor device includes: forming an interlayer insulating film on a substrate; selectively etching the interlayer insulating film to form a recess exposing a portion of the substrate; and forming a bottom electrode contact embedding at least a portion of the recess; forming a variable resistance element on the bottom electrode contact, wherein the bottom electrode contact comprises a Co alloy, a Fe alloy, a Ni alloy, or a Mn alloy comprising at least one selected from the group consisting of Pt, Pd, Al, Ga, B, Ir, and rare earth metals.

These and other features and advantages of the present invention will become better understood by those with ordinary skill in the related art from the description of embodiments together with the following drawings.

### BRIEF DESCRIPTION OF THE DRAWINGS

FIGS. 1A to 1D are perspective and cross-sectional views illustrating semiconductor devices according to comparative examples.

FIGS. 2A to 2C are perspective and cross-sectional views illustrating a semiconductor device according to an embodiment of the present disclosure.

FIGS. 3A to 3G are cross-sectional views to illustrate a semiconductor device and a manufacturing method thereof, according to an embodiment of the present disclosure.

### DETAILED DESCRIPTION

Embodiments of the present disclosure will be described below in more detail with reference to the accompanying drawings. The embodiments may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

Hereinafter, the diverse embodiments of the present disclosure will be described in detail with reference to the attached drawings.

The drawings are not necessarily to scale and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

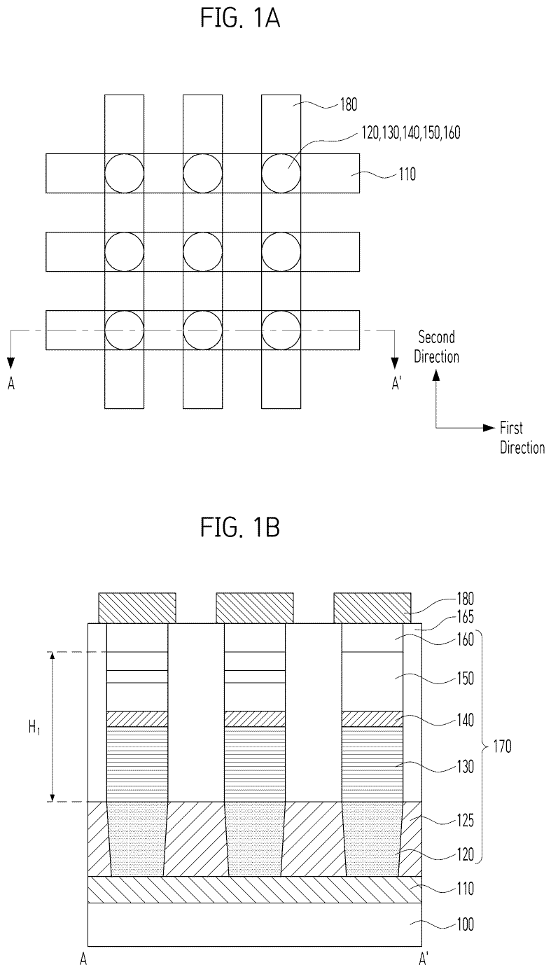

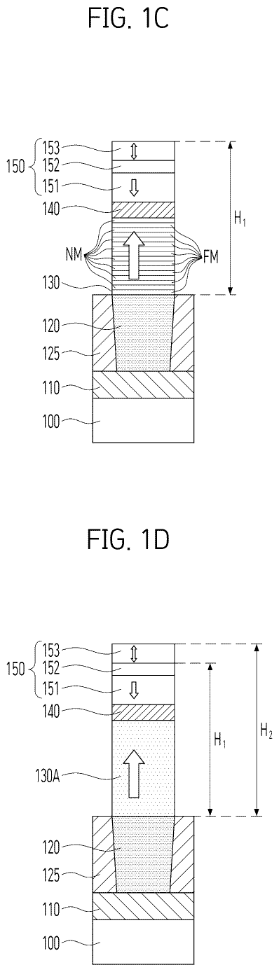

FIGS. 1A to 1D are perspective views and cross-sectional views illustrating a semiconductor device according to a comparative example. FIG. 1A illustrates a plan view, and FIG. 1B illustrates a cross-sectional view along line A-A′ of FIG. 1A.

Referring to FIGS. 1A and 1B, a semiconductor device according to a comparative example may have a crosspoint structure including a first wiring 110 formed on a substrate 100 and extending in a first direction, a second wiring 180 located on the first wiring 110 and extending in a second direction intersecting the first direction, and a memory cell 170 disposed at the respective intersection between the first wiring 110 and the second wiring 180.

The substrate 100 may include a semiconductor material, such as silicon or the like. Within the substrate 100, any desired predetermined substructure (not shown) may be formed. For example, the substructure may include a drive circuit (not shown) electrically connected to control the first wiring 110 and/or the second wiring 180 formed on the substrate 100.

The first wiring 110 and the second wiring 180 may be in communication with the memory cell 170 to deliver voltage or current to the memory cell 170 to drive the memory cell 170. One of the first wiring 110 and the second wiring 180 may function as a word line and the other may function as a bit line. The first wiring 110 and the second wiring 180 may have a single-membrane structure or a multi-membrane structure comprising a conductive material.

The memory cells 170 may be arranged in a matrix form along the first and second directions to overlap with the intersection regions of the first wirings 110 and the second wirings 180. The space between the first wirings 110, the second wirings 180, and the memory cells 170 may be embedded with an insulating material.

The memory cell 170 may include a stacked structure, which may include a bottom electrode contact 120, a shift canceling layer 130, a spacer layer 140, an MTJ layer 150, and a selector layer 160. Further, a first interlayer insulating film 125 may be formed covering the sidewalls of the bottom electrode contact 120, and a second interlayer insulating film 165 may be formed covering the sidewalls of the multi-layer (ML) shift canceling layer 130, spacer layer 140, MTJ layer 150, and selector layer 160.

The shift canceling layer 130 may be formed between the bottom electrode contact 120 and the spacer layer 140. The shift canceling layer 130 may serve to compensate for magnetic shifts through a magnetization direction antiparallel to the fixed layer, which can reduce sensitivity to external magnetic field changes, thereby increasing the reliability of the MTJ device and reducing the occurrence of data errors. In addition, the shift canceling layer 130 may form a synthetic antiferromagnetic (SAF) structure with the fixed layer to increase magnetic stability and control the magnetic hysteresis of the MTJ device, which in turn may allow it to maintain high sensitivity in low magnetic fields. The shift canceling layer 130 can be magnetically coupled to the fixed layer via a spacer layer 140, which is typically composed of a non-magnetic metal such as Ru, Ir, Cr, etc.

The length from the upper surface of the bottom electrode contact 120 to the upper surface of the MTJ layer 150, that is, the height of the variable resistance element H₁ in the semiconductor device according to the present comparative example, will be described with reference to the cross-sectional views illustrating the variable resistance element according to the comparative example of FIGS. 1C and 1D.

FIG. 1C is a cross-sectional view of a variable resistance element having a multilayer shift cancellation layer 130, a spacer layer 140, a fixed layer 151 having a fixed magnetization orientation, a free layer 153 having a changeable magnetization orientation, and a tunnel barrier layer 152 interposed between the fixed layer 151 and the free layer 153, all of which are stacked on the bottom electrode contact 120. The variable resistance element may include the MTJ layer 150 which may include the fixed layer 151, the free layer 153, and the tunnel barrier layer 152.

The multilayer shift canceling layer 130 may have a stacked structure with alternating magnetic layers (FM) and non-magnetic layers (NM) in a repeating structure. For example, this is a structure such as [FM/NM]n, where a combination of each layer forms the desired magnetic properties. The multilayer shift-canceling layer 130 can tune its magnetic properties by adjusting the thickness and composition of the individual layers, can exhibit a synthetic antiferromagnetic (SAF) effect through interlayer coupling, and has relatively low thermal stability due to the potential for interlayer diffusion to occur in high-temperature processes.

In contrast, the alloy shift canceling layer (130A in FIG. 1D) is made of a single material or homogeneous alloy, which has unique magnetic properties. The magnetic properties can be obtained directly from the bulk properties of the material itself, and typically have a high magnetic anisotropy, making them thermally stable and suitable for high-temperature processes.

Referring to FIG. 1D, the multilayer shift canceling layer 130 has low thermal stability and can be replaced by an alloy shift canceling layer 130A, which has high thermal stability. However, while the alloy shift canceling layer 130A is thermally stable, it has a large thickness compared to the multilayer shift canceling layer 130. The alloy shift canceling layer 130A OF FIG. 1D may require a relatively thick layer to have inherent magnetic anisotropy. In particular, Co alloys or rare earth-transition metal alloys with bulk magnetic anisotropy may be limited in forming effective magnetic coupling in thin layers such as multilayer shift canceling layers, requiring a certain thickness to ensure performance. Furthermore, since the alloy shift canceling layer 130A must provide overall properties as a single material, it must be fabricated thicker to maintain performance and stability, and its physical thickness may be larger to achieve magnetic properties such as the multilayer shift canceling layer 130 by being composed of a single material. As a result, the height H₂ of the variable resistance element comprising the alloy shift canceling layer 130A may be higher than the height H₁ of the variable resistance element comprising the multilayer shift canceling layer 130.

The lower height of the variable resistance element allows more devices to be placed in the same area, which can increase the density of the device, which can be an important factor in increasing capacity, especially in memory semiconductors. In addition, the lower height of the variable resistor element allows for shorter paths for current to flow, which in turn may reduce electrical resistance and minimize power losses, while faster signal transmission speeds may reduce power consumption and enable efficient operation of the memory semiconductor. At the same time, heat generation may be reduced.

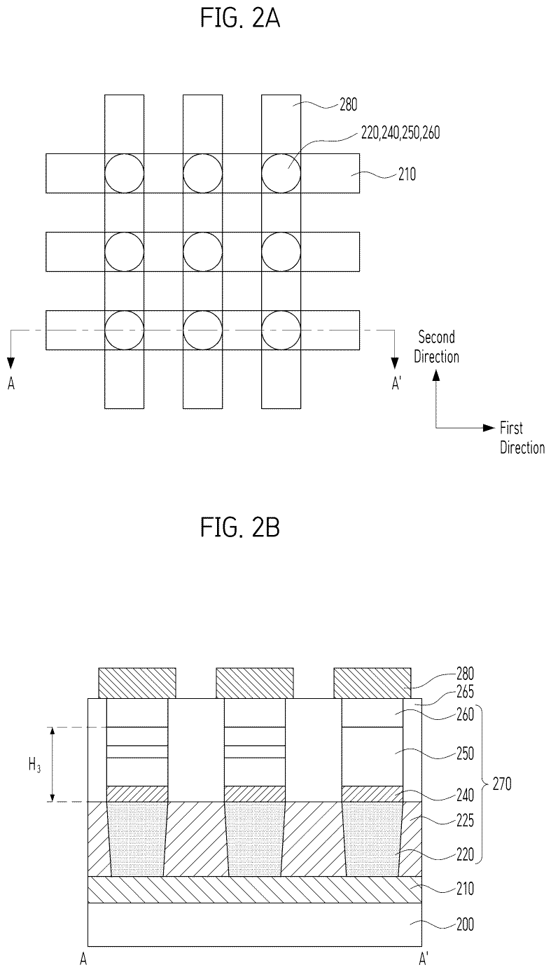

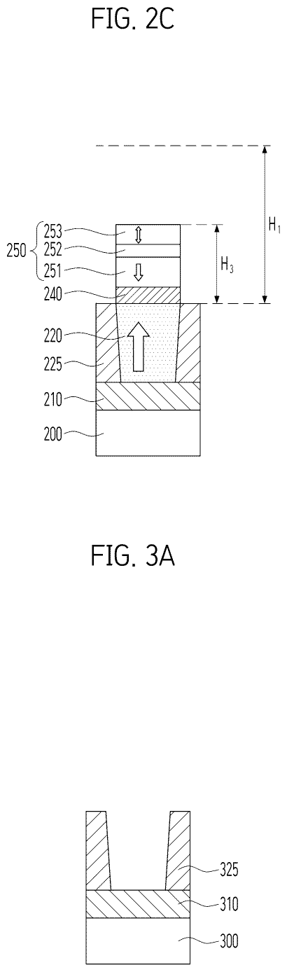

According to an embodiment of the present disclosure, a semiconductor device and a method of manufacturing the same address the problem of thermal stability degradation observed in the multilayer shift cancellation layer 130 of FIG. 1C and the issue of increased variable resistance element height caused by the alloy shift cancellation layer 130A of FIG. 1D. To resolve these issues, the present disclosure provides a method that enhances thermal stability while effectively reducing the height of the variable resistance element by embedding an alloy shift cancellation layer, which simultaneously functions as a shift cancellation layer and a bottom electrode contact, into at least a portion of the recess of the interlayer insulating film using a specific alloy. This will be described in more detail with reference to FIGS. 2A to 2C.

FIGS. 2A and 2B are drawings illustrating a semiconductor memory according to an embodiment of the present disclosure. FIG. 2A illustrates a plan view, and FIG. 2B illustrates a cross-sectional view along line A-A′ of FIG. 2A.

Referring to FIGS. 2A and 2B, a semiconductor memory according to the present embodiment may have a crosspoint structure comprising a first wiring 210 formed on a substrate 200 and extending in a first direction, a second wiring 280 located on the first wiring 210 and extending in a second direction intersecting the first direction, and a memory cell 270 disposed at a respective intersection between the first wiring 210 and the second wiring 280. The semiconductor memory may comprise a plurality of first wirings 210 spaced apart from each other, a plurality of second wirings 280 spaced apart from each other, and a plurality of memory cells 270 disposed at respective intersections between the plurality of the first wirings 210 and the plurality of the second wirings 280.

The substrate 200 may include a semiconductor material, e.g., silicon or the like. Within the substrate 200, any desired predetermined substructure (not shown) may be formed. For example, the substructure may include a drive circuitry (not shown) electrically connected to control the first wiring 210 and/or the second wiring 280 formed on the substrate 200.

The first wirings 210 and the second wirings 280 may be in communication with the memory cells 270 to deliver voltage or current to the memory cells 270 to drive the memory cells 270. One of the first wirings 210 and the second wirings 280 may function as word lines and the other may function as bit lines. The first wirings 210 and the second wirings 280 may have a single-membrane structure or a multi-membrane structure comprising a conductive material. Examples of conductive materials may include, but are not limited to, metals, metal nitrides, conductive carbon materials, or combinations thereof. For example, first wiring 210 and second wiring 280 may comprise tungsten (W), titanium (Ti), tantalum (Ta), platinum (Pt), aluminum (Al), copper (Cu), zinc (Zn), nickel (Ni), cobalt (Co), lead (Pd), tungsten nitride (WN), tungsten silicide (WSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), carbon (C), silicon carbide (SiC), silicon carbon nitride (SiCN), or any combination thereof.

The memory cells 270 may be arranged in a matrix form along the first and second directions to overlap the intersection areas of the first wiring 210 and the second wiring 280. In this embodiment, the memory cells 270 may have a size less than or equal to the intersection areas of the first wirings 210 and the second wirings 280, but in other embodiments, the memory cells 270 may have a size greater than these intersection areas. The space between the first wirings 210, the second wirings 280, and the memory cells 270 may be embedded with an insulating material.

The memory cell 270 may include a stacked structure, wherein the stacked structure may include a bottom electrode contact 220, a spacer layer 240, an MTJ layer 250, and a selector layer 260. Further, a first interlayer insulating film 225 may be formed covering the sidewalls of the bottom electrode contact 220. Also, a second interlayer insulating film 265 may be formed covering the sidewalls of the spacer layer 240, the MTJ layer 250, and the selector layer 260.

The first interlayer insulating film 225 and the second interlayer insulating film 265 may include an insulating material, polysilicon (Poly-Si), or any combination thereof, and may be organized in a single-membrane structure or a multi-membrane structure. For example, the first interlayer insulating film 225 and the second interlayer insulating film 265 may include silicon oxide, silicon nitride, silicon oxynitride, and/or low-k material. Materials with a dielectric constant (k) of 4 or less are generally referred to as low-k materials, and lower values provide better electrical insulation properties, reducing parasitic capacitance between devices. A semiconductor memory according to the present embodiment may have a crosspoint structure comprising a first wiring 210 formed on a substrate 200 and extending in a first direction, a second wiring 280 located on the first wiring 210 and extending in a second direction intersecting the first direction, and a memory cell 270 disposed at a respective intersection between the first wiring 210 and the second wiring 280. These low-k materials include, but are not limited to, silicon oxides, organosiloxanes, silicon carbide, organic-based materials including benzene rings or fluorine, and void materials.

The bottom electrode contact 220 may be formed between the first wiring 210 and the spacer layer 240. The bottom electrode contact 220 may be located at the bottom of the memory cell 270, and may be electrically connected to the first wiring 210. The bottom electrode contact 220 may function as a conduit for transferring current or voltage between the first wiring 210 and the memory cell 270.

The bottom electrode contact 220 may function not only as a conduit for carrying current or voltage between the first wiring 210 and the memory cell 270, but also as a shift cancellation layer that compensates for magnetic shifts through a magnetization direction antiparallel to the fixed layer of the MTJ layer 250. This may reduce the sensitivity to external magnetic field changes, which may in turn improve the reliability of the MTJ device and reduce the occurrence of data errors. The bottom electrode contact 220 may function as a shift-canceling layer and may have a magnetization direction that is antiparallel to the fixed layer of the MTJ layer 250 and may serve to suppress unwanted magnetization changes in the magnetic material due to external magnetic fields. By setting the magnetization direction antiparallel to the fixed layer of the MTJ layer 250, the unnecessary magnetization switching that may be caused by the external magnetic field may be offset and the effect of increasing stability may be exerted. This in turn may reduce magnetic noise in the memory device, enabling the MTJ device to maintain a constant state and to ensure accurate storage and reading of data.

The bottom electrode contact 220 may function simultaneously both as the shift canceling layer and the bottom electrode contact by including a Co alloy, Fe alloy, Ni alloy, or Mn alloy comprising at least one selected from the group consisting of platinum (Pt), palladium (Pd), aluminum (Al), gallium (Ga), boron (B), iridium (Ir), zirconium (Zr), hafnium (Hf), and rare earth metals. These alloys are suitable as materials for the bottom electrode contact because they allow for gap filling in the recessed areas, shift canceling and simultaneous formation of synthetic antiferromagnetism (SAF) perpendicular to the fixed layer, as well as maintaining perpendicular magnetic anisotropy (PMA) at high temperatures, and no degradation of the synthetic antiferromagnetic properties. While gap-fillable materials may have been employed for bottom electrode contact in the past, the inventors have surprisingly discovered the first such alloy that simultaneously functions as a shift-canceling layer while simultaneously filling the gap, and does not degrade at high temperatures.

Specifically, the bottom electrode contact 220 can include a Co alloy comprising Pt, an ordered phase alloy, or a rare earth-transition metal (RE-TM) alloy. Co alloys comprising Pt increase the corrosion resistance and thermal stability of the alloy by including Pt, and are also more conductive, making them suitable for the role of the bottom electrode contact. Ordered phases alloys are well-suited to the role of bottom electrode contact because their structural stability and predictable magnetic and electronic properties allow for consistent conductivity and increased device reliability. In addition, rare earth-transition metal (RE-TM) alloys offer strong magnetic properties and stable layer formation, which can minimize diffusion and enhance the interface stability of the bottom electrode contact.

Co alloys comprising Pt may consist of Co and Pt alone, or may comprise additional elements in addition to Co and Pt. For example, CoPt alloys have high magnetic anisotropy, which makes them suitable as shift cancellation layers, and in particular, CoPt alloys with L1₀ alignment can be advantageous for keeping the magnetization orientation stable, thereby reducing sensitivity to external magnetic fields. CoPt₃ alloys offer high magnetic anisotropy and low domain switching coercivity, which can be useful for maintaining stable magnetic properties. CoCrPt alloys have the effect of increasing magnetic stability and durability, which can further enhance their function as a shift-canceling layer. The addition of Cr increases corrosion resistance and can maintain stable magnetic performance in high temperature environments.

Ordered phase alloys consist of alloys with special structures designed to be magnetic and have stable magnetic properties, and can include, for example, CoPt, NiPt, FePt, FePd, MnAl, MnGa, NiPt, CoZr, CoHf, Co₃Pt alloys. CoPt alloys with an L1₀ structure, in which the ratio of Co to Pt is aligned 1:1, provide high magnetic anisotropy and stable magnetization orientation, which may be suitable as a shift-canceling layer to compensate for magnetic shifts. FeNi alloys with an L1₀ structure composed of Fe and Ni have high magnetic anisotropy and may be suitable for use as a shift-canceling layer in memory cells. FePt alloys with an L1₁ structure, in which Fe and Pt are aligned, offer high magnetic stability and can maintain good magnetic properties even in high-temperature environments, making them suitable as shift-canceling layers. Co₃Pt alloys with D0₁₉ structure have Co and Pt arranged in a specific arrangement and can provide high magnetic stability. Co₃Pt alloys have high resistance to external magnetic fields, which may make it suitable for use as a shift canceling layer.

Rare earth-transition metal alloys are alloys that combine rare earth (RE) metals with transition metals (TM) and have high magnetic anisotropy, which means that the direction of magnetization can be controlled, resulting in high magnetic stability. In addition, rare earth-transition metal alloys can have a high magnetization rate, which means they can easily change their magnetization direction under the influence of a magnetic field. These properties make them suitable for performing functions such as magnetic shifting. Rare earth-transition metals can include, for example, TbFe, GdCo, DyFe, HoFe, NdFeB, SmCo, LaCoO₃, GdFe₂, TbDyFe, PrCo, and others. TbFe alloys have high magnetic anisotropy and high magnetic stability, which allows them to be used as shift canceling layers and maintain stable magnetic properties even at high temperatures. GdCo alloys offer high magnetization rates and strong magnetic interactions, which are effective as shift cancellation layers and can be suitable for applications where maintaining magnetic properties is important, especially at high temperatures. DyFe alloys offer high magnetic stability and strong magnetic properties, which is advantageous when used as a shift canceling layer to compensate for magnetic shifts. HoFe alloys offer strong magnetic anisotropy and high magnetic stability, and are effective as a shift canceling layer. NdFeB alloys offer high magnetic anisotropy and very high magnetization rates, making them strong shift canceling layers. NdFeB alloys can effectively perform shift cancellation while providing strong magnetic properties.

The selector layer 260 may be implemented as a thin film within the memory cells 270 and may function to control electrical access to any of the plurality of memory cells 270 in an array, while preventing current leakage that may occur between memory cells 270 sharing the first wiring 210 or the second wiring 280. To this end, the selector layer 260 may have threshold switching characteristics that allow it to block current or flow little current when the magnitude of the voltage supplied to its top and bottom sides is below a predetermined threshold voltage, and then allow current to flow rapidly above this threshold voltage. That is, the selector layer 260 may be turned on above the threshold voltage and turned off below the threshold voltage. In one embodiment, the selector layer 260 may include a dopant-infused insulating material.

In a semiconductor device according to the present embodiment, a length from the upper surface of the bottom electrode contact 220 to the upper surface of the MTJ layer 250, that is, the height of the variable resistance element H₃, will be described with reference to a cross-sectional view illustrating a variable resistance element according to an embodiment of FIG. 2C.

FIG. 2C is a cross-sectional view illustrating a variable resistance element in which an MTJ layer 250, comprising a spacer layer 240, a fixed layer 251 having a fixed magnetization direction, a free layer 253 having a changeable magnetization direction, and a tunnel barrier layer 252 interposed between the fixed layer 251 and the free layer 253, is stacked on the bottom electrode contact formed of the aforementioned Co alloys comprising Pt, the ordered phase alloys, or the rare earth-transition metal alloys, and simultaneously functioning as a shift-canceling layer.

The free layer 253 and the fixed layer 251 may include a material having interfacial vertical magnetic anisotropy. Interfacial vertical magnetic anisotropy refers to a phenomenon in which a magnetic layer with an intrinsic horizontal magnetization characteristic has a vertical magnetization direction due to the influence from the interface with another layer adjacent to it. Here, the intrinsic horizontal magnetization characteristic means that in the absence of external factors, the magnetic layer has a magnetization direction parallel to its widest surface. For example, if a magnetic layer with an intrinsic horizontal magnetization characteristic is formed on a substrate and there are no external factors, the magnetization direction of the magnetic layer may be substantially parallel to the top surface of the substrate. Each of the free layer 253 and the fixed layer 251 may have a single-membrane structure or a multi-membrane structure comprising a ferromagnetic material. The ferromagnetic material may include an alloy based on Fe, Ni, or Co, such as an Fe—Pt alloy, Fe—Pd alloy, Co—Fe alloy, Co—Pd alloy, Co—Pt alloy, Co—Fe—Ni alloy, Fe—Ni—Pt alloy, Co—Fe—Pt alloy, Co—Ni—Pt alloy, Co—Fe—B alloy, or the like, or may include a laminated structure, such as Co/Pt, Co/Pd, or the like. The positions of the free layer 253 and the fixed layer 251 may be reversed across the tunnel barrier layer 252. For example, the free layer 253 may be positioned above the tunnel barrier layer 252 and the fixed layer 251 may be positioned below the tunnel barrier layer 252 and above the bottom electrode pattern 221. The tunnel barrier layer 252 may enable tunneling of electrons between the free layer and the fixed layer during a write operation that changes the resistance state of the variable resistance element, causing the magnetization direction of the free layer 253 to change. The tunnel barrier layer 252 may include at least one of an oxide of magnesium (Mg), an oxide of titanium (Ti), aluminum (Al), an oxide of magnesium-zinc (MgZn), an oxide of magnesium-boron (MgB), a nitride of titanium (Ti), and a nitride of vanadium (V). In one embodiment, the tunnel barrier layer 252 may be a monolayer of magnesium oxide (MgO). Alternatively, the tunnel barrier layer 252 may comprise a plurality of layers. The free layer 253, the tunnel barrier layer 252, and the fixed layer 251 may form the MTJ layer 250.

The electrical resistance of the MTJ layer 250 may be dependent on the magnetization directions of the fixed layer 251 and the free layer 253. For example, the electrical resistance of the MTJ layer 250 may be much greater when the magnetization directions of the fixed layer 251 and the free layer 253 are antiparallel than when they are parallel. As a result, the electrical resistance of the MTJ layer 250 can be adjusted by changing the magnetization direction of the free layer 253, which can be used as a data storage principle in a semiconductor device according to the present disclosure.

Since the shift canceling layer is embedded in the recessed portion of the first interlayer insulating film 225, the height H₃ of the variable resistance element of the present embodiment can be as low as the height of the multilayer shift canceling layer 130 according to the comparative example of FIG. 1C or the height of the alloy shift canceling layer 130A according to the comparative example of FIG. 1D. Thus, the height H₂ of the variable resistor element according to the comparative example of FIG. 1D may be the highest, the height H₁ of the variable resistor element according to the comparative example of FIG. 1C may be the next highest, and the height H₃ of the variable resistor element of the present embodiment may be significantly lower compared to them. Accordingly, in the semiconductor device according to the present embodiment, more devices can be arranged in the same area, thereby increasing device density, and shortening the path through which current flows, thereby reducing electrical resistance and minimizing power loss. In addition, the signal transmission speed may be increased, which may reduce power consumption and enable efficient operation of the memory semiconductor, while also at the same time reducing heat generation.

If a high temperature heat treatment is applied to the multilayer shift-canceling layer 130 according to the comparative example of FIG. 1C, inter-diffusion may occur, resulting in degradation of the synthetic antiferromagnetic properties. In contrast, the bottom electrode contact 220 in this embodiment is made of a Co alloy comprising platinum (Pt), an ordered phase alloy, or a rare earth-transition metal (RE-TM) alloy, which has excellent thermal stability and is suitable for high temperature processing. This may enable high temperature processing, which in turn may allow for the improvement of the magnetoresistance (MR) of the MTJ layer (250). At the same time, the alloy shift canceling layer 130A according to the comparative example of FIG. 1D may enable an increase in magnetoresistance and exchange bias field, but the height of the variable resistance element may increase due to the low magnetic saturation strength (Ms)*thickness (t). However, in the semiconductor device of the present embodiment, the bottom electrode contact 220 may also function as a shift canceling layer, so the height of the variable resistance element may be reduced along with the increase in the magnetoresistance and exchange bias field of the MTJ layer 250.

As a shift canceling layer, the bottom electrode contact 220 may serve to offset or reduce the influence of stray magnetic fields generated by the fixed layer 251, thereby reducing the influence of the stray magnetic fields on the free layer 253, and resulting in a lower deflected magnetic field in the free layer 253. This may negate the shift in the magnetization reversal characteristic (hysteresis curve) of the free layer 253 induced by the fixed layer 251.

To this end, the bottom electrode contact 220 may have a magnetization direction that is antiparallel to the magnetization direction of the fixed layer 251, for example, if the magnetization direction of the fixed layer 251 is from top to bottom, the bottom electrode contact 220 may have a magnetization direction that is from bottom to top, and conversely, if the magnetization direction of the fixed layer 251 is from bottom to top, the bottom electrode contact 220 may have a magnetization direction that is from top to bottom. Further, the bottom electrode contact 220 may be antiferromagnetically exchange-coupled with the fixed layer 251 via the spacer layer 240 to form a synthetic anti-ferromagnet (SAF) structure.

By using a specific alloy as the bottom electrode contact 220 in the present embodiment, there are fewer interlayer junctions and the interfacial energy and interfacial diffusion problems that may occur in a multilayer shift canceling layer may be reduced, which may further improve thermal stability in high-temperature processes. Furthermore, the monolayer structure of the bottom electrode contact 220 fabricated with the alloy may simplify the fabrication process, resulting in higher production efficiency, and may maintain higher magnetic properties by reducing interlayer scattering, which allows it to function more effectively as a shift canceling layer.

For multilayer shift canceling layers, it may be difficult to uniformly embed them in the recessed area due to the multilayer structure, where each layer is individually composed. This is because the junction between the layers in the recessed area may not be smooth, making it difficult to maintain thickness uniformity and interfacial consistency, and may lead to inconsistent thermal and magnetic properties. On the other hand, the bottom electrode contact 220 made of the alloy is composed of a uniform monolayer, which facilitates embedding in the recessed area, which can simultaneously improve the consistency of the manufacturing process and the reliability of the device.

A material layer (not shown) may be interposed between the fixed layer 251 and the bottom electrode contact 220 to bridge lattice structure differences and lattice mismatches between the fixed layer 251 and the bottom electrode contact 220. For example, such a material layer may be amorphous and may further comprise a conductive material, e.g., a metal, metal nitride, metal oxide, or the like.

The spacer layer 240 may be interposed between the fixed layer 251 and the bottom electrode contact 220 to act as a buffer between them and to enhance the properties of the bottom electrode contact 220 as a shift canceling layer. In particular, the fixed layer 251 and the bottom electrode contact 220 may be antiferromagnetically exchange-coupled via a spacer layer 240 to form a synthetic antiferromagnetic (SAF) structure. The spacer layer 240 may include a noble metal, such as Ru, Ir, Cr, or any combination thereof. For example, the spacer layer 240 may have a thickness of 0.5 nm or more. As such, the thicker thickness of the spacer layer 240 can prevent degradation of its properties by subsequent heat treatment processes and can improve the strength of the antiferromagnetic exchange coupling between the fixed layer 251 and the bottom electrode contact 220.

Additionally, an intermediate layer (not shown) may be interposed between the tunnel barrier layer 252 and the fixed layer 251. The intermediate layer may be a magnetic layer that is the closest to the tunnel barrier layer 252, and may include Co, Fe, Ni, B, other noble metals, or combinations thereof.

A variable resistance element including a spacer layer 240 and an MTJ layer 250 may function to store different data by switching between different resistance states depending on the voltage or current applied through the top and bottom. The variable resistance element can include metal oxides such as transition metal oxides, perovskite materials, and the like utilized in RRAM, PRAM, FRAM, MRAM, and the like, phase change materials such as chalcogenide materials, ferroelectric materials, ferromagnetic materials, and the like. The variable resistance element may have a single membrane structure or a multi-membrane structure in which a combination of two or more membranes exhibit variable resistance characteristics.

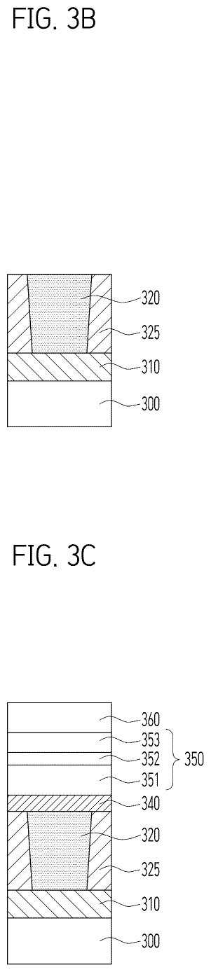

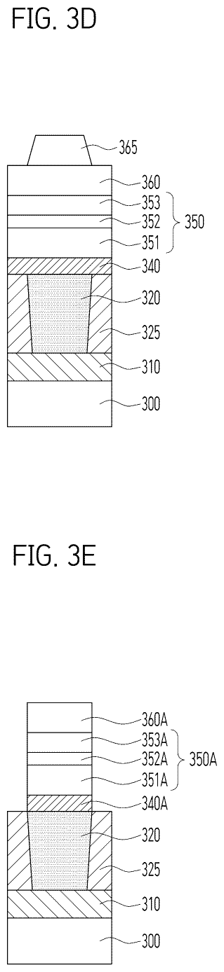

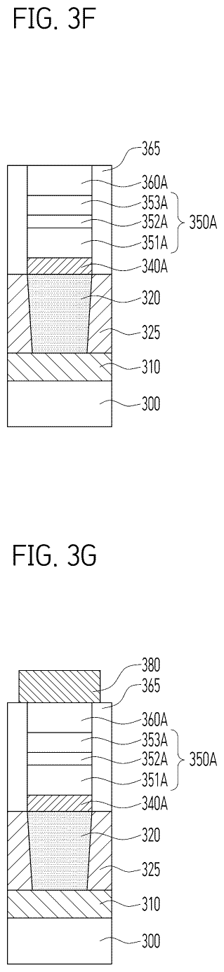

FIGS. 3A to 3G are cross-sectional views for illustrating a semiconductor device and a manufacturing method thereof according to an embodiment of the present disclosure, and are magnified cross-sectional views of only one memory cell of the plurality of memory cells. As the parts are substantially the same as the foregoing embodiments, a detailed description may be omitted.

First, the manufacturing method will be described.

Referring to FIGS. 3A and 3B, a first wiring 310 may be formed on a substrate 300 in which a predetermined substructure (not shown) is formed. The first wiring 310 may be formed by forming an interlayer insulating film having a trench for forming the first wiring 310 on the substrate 300, forming a conductive layer for forming the first wiring 310 in the trench, and etching it using a mask pattern in the shape of a line extending in a first direction.

Subsequently, a bottom electrode contact 320 can be formed on the first wiring 310. The bottom electrode contact 320 may be formed by forming an interlayer insulating film 325 having holes on the structure in which the first wiring 310 is formed, forming a material layer for forming the bottom electrode contact 320 on the holes, and then performing a planarization process, such as a chemical mechanical planarization process. Specifically, a photolithography and etching process may create precisely sized holes at locations where the bottom electrode contacts 320 are to be placed, and may fill the formed holes with a material layer suitable for the bottom electrode contact 320. The material that is suitable for the bottom electrode contact 320 may include a Co alloy, Fe alloy, Ni alloy, or Mn alloy comprising at least one selected from the group consisting of Pt, Pd, Al, Ga, B, Ir, and rare earth metals. These alloys may have high corrosion resistance, thermal stability, and conductivity to function as the bottom electrode contact, while also providing high magnetic stability, and also function as a shift canceling layer by maintaining good magnetic properties even in high temperature environments. Deposition methods may include sputtering or chemical vapor deposition (CVD). After deposition, a chemical mechanical planarization (CMP) process may be performed to planarize the surface so that the material filled inside the holes does not spill over the surface of the first interlayer insulating film 325. Through this, the bottom electrode contact 320 may be planarized and formed to the same height as the surface of the first interlayer insulating film 325. The bottom electrode contact 320 formed through this gap filling method has high corrosion resistance, thermal stability, and conductivity to serve as a bottom electrode contact, as well as magnetic properties that allow it to function as a shift canceling layer. The formed bottom electrode contact 320 may have an antiparallel magnetization direction to the fixed layer (351A in FIG. 3G), which may offset unnecessary magnetization shifts that may be caused by an external magnetic field and have the effect of increasing stability.

Referring to FIG. 3C, a material layer for forming a spacer layer 340 may be formed, on the planarized bottom electrode pattern 320 and the first interlayer insulating film 325, followed by the formation of a material layer for forming a fixed layer 351, a material layer for forming a tunnel barrier layer 352, and a material layer for forming a free layer 353, all of which are included in a material layer for forming an MTJ layer 350. Subsequently, a material layer for forming a selector layer 360 can be formed. The formation of the material layer for the formation of the fixed layer 351 and the material layer for the formation of the free layer 353 may be deposited by physical vapor deposition (PVD), chemical vapor deposition (CVD), or e-beam deposition. The material layer for the formation of the tunnel barrier layer 352 may be deposited by alkali metal oxide or atom layer deposition (ALD). This method allows for a very thin and uniform oxide film, which allows for precise control of the tunneling current.

The spacer layer (340A in FIG. 3G) may be interposed between the fixed layer 351A in FIG. 3G and the bottom electrode contact 320 which may function as a shift-canceling layer, to serve as a buffer between them, implementing antiferromagnetic exchange coupling of the fixed layer 351A and the bottom electrode contact 320, and enhancing the properties of the bottom electrode contact 320. The spacer layer 340A may include a noble metal, such as Ru, Ir, Cr, or any combination thereof. For example, the spacer layer 340A may have a thickness of 0.5 nm or more. As such, a thickness of the spacer layer 340A of 0.5 nm or more can prevent diffusion or interaction between materials that may occur during a high temperature heat treatment process. The thicker spacer layer may act to block any deformation or reaction of the material that may occur at high temperatures, thereby protecting the fixed layer 351A and the bottom electrode contact 320 from any property changes or degradation. As a result, the fixed layer 351A and the bottom electrode contact 320 can maintain stability at high temperatures. Furthermore, when the thickness of the spacer layer 340A is 0.5 nm or more, the antiferromagnetic exchange bond between the fixed layer 351A and the bottom electrode contact 320 may be stronger. This is because the spacer layer 340A can more effectively modulate the interaction between the fixed layer 351A and the bottom electrode contact 320, thereby better controlling the magnetization direction of the fixed layer 351A and increasing the magnetic stability.

Referring to FIGS. 3D and 3E, a hardmask layer 365 in the form of a pillar can be deposited on the top surface of the material layer for forming the selector layer 360. The hardmask layer 365 can be formed from an insulating material such as silicon nitride or silicon oxynitride. For example, the hardmask layer 365 may comprise at least one of carbon (C), silicon (Si), copper (Cu), tungsten (W), titanium (Ti), tantalum (Ta), aluminum (Al), and nitrides, oxides, borides, and metal nitrides comprising them (e.g., titanium nitride and tantalum nitride). A material layer for forming a spacer layer 340, a material layer for forming a fixed layer 351, and a material layer for forming a tunnel barrier layer 352, material layer for forming the free layer 353, and material layer for forming the selector layer 360 can be selectively etched using a hardmask layer 365 in the form of a pillar as an etch barrier to form the pillar-shaped patterned spacer layer 340A, fixed layer 351A, tunnel barrier layer 352A, free layer 353A, and selector layer 360A. The MTJ layer 350A may consist of the fixed layer 351A, the tunnel barrier layer 352A, and the free layer 353A.

Referring to FIG. 3F, a second interlayer insulating film 365 can be formed covering the sidewalls of the spacer layer 340A, the MTJ layer 350A including the fixed layer 351A, the tunnel barrier layer 352A and the free layer 353A, and the selector layer 360A. The second interlayer insulating film 365 may comprise a highly insulating material, such as an insulating material, polysilicon (Poly-Si), or any combination thereof, which may provide stability at high temperatures to prevent damage in subsequent processing. The second interlayer insulating film 365 may be deposited to uniformly cover the sidewalls of the MTJ layer 350A and selector layer 360A via chemical vapor deposition (CVD), atomic layer deposition (ALD), or sputtering processes. This allows for electrical isolation of each memory cell along the sidewalls of MTJ layer 350A and selector layer 360A, minimizing surface conductivity and leakage current.

Referring to FIG. 3G, a second wiring 380 may be formed on top of the memory cell. The second wiring 380 may be formed by first forming a trench, depositing a conductive layer in the trench, and etching the conductive layer using a line-shaped mask pattern (not shown) extending in a second direction. The second wiring 380 may be patterned at 90 degrees to the first wiring 310, i.e., the first wiring 310 may be formed to extend in the first direction of FIG. 2A, and the second wiring 380 may be formed to extend in the second direction of FIG. 2A. This may result in a semiconductor device having a crosspoint structure in which a memory cell is disposed between the first wiring 310 and the second wiring 380 at a region overlapping the area where they intersect each other.

By the above process, a semiconductor device according to an embodiment of the present disclosure may be formed. Referring again to FIG. 3G, a semiconductor device according to an embodiment of the present disclosure may include a substrate 300, a first wiring 310, a bottom electrode contact 320, a spacer layer 340A, an MTJ layer 350A including a fixed layer 351A, a tunnel barrier layer 352A and a free layer 353A, a selector layer 360A, and a second wiring 380. The device may further include a first interlayer insulating film 325 covering a side wall of the bottom electrode contact 320, and a second interlayer insulating film 365 covering a side wall of the spacer layer 340A, the MTJ layer 350A including the fixed layer 351A, the tunnel barrier layer 352A and the free layer 353A, and the selector layer 360A. The process structure of FIG. 3G may be substantially the same as the process structure of FIG. 2B described above. That is, the substrate 300, the first wiring 310, the bottom electrode contact 320, the first interlayer insulating film 325, the spacer layer 340A, the MTJ layer 350A, the selector layer 360A, the second interlayer insulating film 365, and the second wiring 380 may each be the same as the substrate 200, first wiring 210, bottom electrode contact 220, first interlayer insulating film 225, spacer layer 240, MTJ layer 250, selector layer 260, second interlayer insulating film 265, and second wiring 280 of FIG. 2B, respectively. Accordingly, a detailed description of the process structure and corresponding parts of FIG. 2B has been omitted above.

According to the semiconductor device described above and the manufacturing method thereof, the bottom electrode contact 320 made of a specific alloy simultaneously functions as a shift-canceling layer, thereby effectively reducing the height of the variable resistance element while increasing its thermal stability. That is, by reducing the height of the variable resistance element simultaneously with an increase in magnetoresistance (MR) and an increase in the exchange bias field, high device integration and high capacity of the semiconductor device can be achieved. Even with the present embodiment, all advantages described in the preceding embodiments can be obtained.

According to the embodiments of the present disclosure, the semiconductor device and the fabrication method thereof may achieve an increase in magnetoresistance (MR) and an increase in exchange bias (Hex) by reducing the height of a variable resistance element while enabling high-temperature heat treatment, and may form a layer that simultaneously functions as a shift canceling layer (SCL) and a bottom electrode contact without forming a separate shift canceling layer (SCL) using a specific alloy.

While the embodiments of the present disclosure has been described with respect to specific embodiments, it will be apparent to those skilled in the art that various changes and modifications may be made without departing from the technical concepts and scope of the present disclosure as defined in the following claims. Furthermore, the embodiments may be combined to form additional embodiments.

What is claimed is:

1. A semiconductor device comprising:
an interlayer insulating film disposed on a substrate, the interlayer insulating film having a recess exposing a portion of the substrate;
a bottom electrode contact (BEC) embedded in at least a portion of the recess; and
a magnetic tunnel junction (MTJ) layer disposed on the interlayer insulating film and the bottom electrode contact,
wherein the bottom electrode contact includes a Co alloy, Fe alloy, Ni alloy, or Mn alloy comprising at least one selected from the group consisting of Pt, Pd, Al, Ga, B, Ir, Zr, Hf, and rare earth metals.

2. The semiconductor device of claim 1, wherein the MTJ layer comprises a fixed layer having a fixed magnetization direction, a free layer having a changeable magnetization direction, and a tunnel barrier layer interposed between the free layer and the fixed layer.

3. The semiconductor device of claim 2, wherein the bottom electrode contact has a magnetization direction antiparallel to the fixed layer.

4. The semiconductor device of claim 1, wherein the bottom electrode contact comprises the Co alloy.

5. The semiconductor device of claim 1, wherein the bottom electrode contact comprises the Co alloy or the Fe alloy comprising rare earth metals.

6. The semiconductor device of claim 2, further comprising a spacer layer interposed between the fixed layer and the bottom electrode contact,
wherein the fixed layer and the bottom electrode contact are antiferromagnetically exchange-coupled through the spacer layer to form a synthetic antiferromagnetic (SAF) structure.

7. The semiconductor device of claim 6, wherein the spacer layer comprises Ru, Ir, Cr, or any combination thereof.

8. The semiconductor device of claim 6, wherein the spacer layer has a thickness of 0.5 nm or more.

9. The semiconductor device of claim 2, further comprising an intermediate layer interposed between the fixed layer and the tunnel barrier layer.

10. The semiconductor device of claim 9, wherein the intermediate layer comprises Co, Fe, Ni, B, a noble metal, or any combination thereof.

11. A method for fabricating a semiconductor device, the method comprising:
forming an interlayer insulating film on a substrate;
selectively etching the interlayer insulating film to form a recess exposing a portion of the substrate;
forming a bottom electrode contact that embeds at least a portion of the recess; and
forming a variable resistance element on the bottom electrode contact,
wherein the bottom electrode contact comprises a Co alloy, Fe alloy, Ni alloy, or Mn alloy comprising at least one selected from the group consisting of Pt, Pd, Al, Ga, B, Ir, and rare earth metals.

12. The method of claim 11, wherein forming a variable resistance element comprises:
forming an MTJ layer comprising a fixed layer having a fixed magnetization direction, a tunnel barrier layer, and a free layer having a changeable magnetization direction sequentially stacked on the bottom electrode contact.

13. The method of claim 12, wherein the bottom electrode contact has a magnetization direction antiparallel to the fixed layer.

14. The method of claim 11, wherein the bottom electrode contact comprises the Co alloy.

15. The method of claim 11, wherein the bottom electrode contact comprises the Co alloy or the Fe alloy comprising rare earth metals.

16. The method of claim 12, further comprising forming a spacer layer on the bottom electrode contact before forming an MTJ layer,
wherein the fixed layer and the bottom electrode contact are antiferromagnetically exchange-coupled through the spacer layer to form a synthetic antiferromagnetic (SAF) structure.

17. The method of claim 16, wherein the spacer layer comprises Ru, Ir, Cr, or any combination thereof.

18. The method of claim 16, wherein the spacer layer has a thickness of 0.5 nm or more.

19. The method of claim 12, further comprising forming an intermediate layer between the fixed layer and the tunnel barrier layer.

20. The method of claim 19, wherein the intermediate layer comprises Co, Fe, Ni, B, a noble metal, or any combination thereof.
